(19) United States
(12) Patent Application Publication
(10) Pub. No.: US 2006/0281306 A1
(43) Pub. Date: Dec. 14, 2006

(54) Carbon nanotube interconnect contacts

(76) Inventors: Florian Gstrein, Portland, OR (US); Adrien R. Lavoie, St. Helens, OR (US); Valery Dubin, Portland, OR (US); Juan E. Dominguez, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/148,614

(22) Filed: Jun. 8, 2005

(51) Int. Cl. H01L 21/44

(52) U.S. Cl. 438/666

(57) ABSTRACT

A method for forming an interconnect on a semiconductor substrate comprises providing at least one carbon nanotube within a trench, etching at least one portion of the carbon nanotube to create an opening, conformally depositing a metal layer on the carbon nanotube through the opening, and forming a metallized contact at the opening that is substantially coupled to the carbon nanotube. The metal layer may be conformally deposited on the carbon nanotube using an atomic layer deposition process or an electroless plating process. Multiple metal layers may be deposited to substantially fill voids within the carbon nanotube. The electroless plating process may use a supercritical liquid as the medium for the plating solution. The wetting behavior of the carbon nanotube may be modified prior to the electroless plating process to increase the hydrophilicity of the carbon nanotube.

### BACKGROUND

Carbon nanotubes are graphene cylinders whose ends are often closed by caps including pentagonal rings. The nanotube is a hexagonal network of carbon atoms forming a seamless cylinder. These cylinders can be as little as a nanometer in diameter with lengths of tens of microns or more in some cases. Depending on how they are made, the carbon nanotubes can be single walled or multiple walled.

Carbon nanotubes may exhibit various electrical properties. Depending on the configuration, carbon nanotubes may either act as semiconductors or as conductors. For example, certain types of carbon nanotubes may exhibit a number of metallic characteristics. Among these metallic characteristics, a number of properties are of particular interest with respect to the use of carbon nanotubes as an addition to, or as a replacement for, copper metal in the interconnect structures of semiconductor chips. Carbon nanotubes have been shown to have higher electrical and thermal conductivity than copper. Carbon nanotubes have also been shown to have higher electromigration resistance than copper, and electromigration has become a larger problem as copper interconnects have become narrower. Composite materials made of carbon nanotubes and copper metal have also been shown to have higher electrical conductivity and higher electromigration resistance than copper alone.

Unfortunately, conventional interconnect structures formed using carbon nanotubes do not completely utilize the full current carrying capacity of the grapheme sheets that form the nanotubes.

### BRIEF DESCRIPTION OF THE DRAWINGS

FIG. 1 illustrates a carbon nanotube interconnect.

FIGS. 2A and 2B are cross-sectional front and side views of a conventional electrical contact to a carbon nanotube bundle.

FIGS. 2C and 2D are cross-sectional front and side views of a conventional electrical contact to a multi-walled carbon nanotube.

FIGS. 3A and 3B are cross-sectional front and side views of a carbon nanotube bundle that is filled with a metal.

FIG. 3C is a cross-sectional side view of a carbon nanotube bundle that is partially filled with a metal.

FIGS. 4A and 4B are cross-sectional front and side views of a multi-walled carbon nanotube that is filled with a metal.

FIG. 4C is a cross-sectional side view of a multi-walled carbon nanotube that is partially filled with a metal.

FIG. 5 is a method of forming a carbon nanotube interconnect structure in accordance with an implementation of the invention.

FIGS. 6A to 6D illustrate the method of FIG. 5.

FIG. 7 is a method of forming a carbon nanotube interconnect structure in accordance with another implementation of the invention.

### DETAILED DESCRIPTION

Described herein are systems and methods of realizing a greater portion of the current-carrying potential of carbon nanotubes used in an interconnect. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

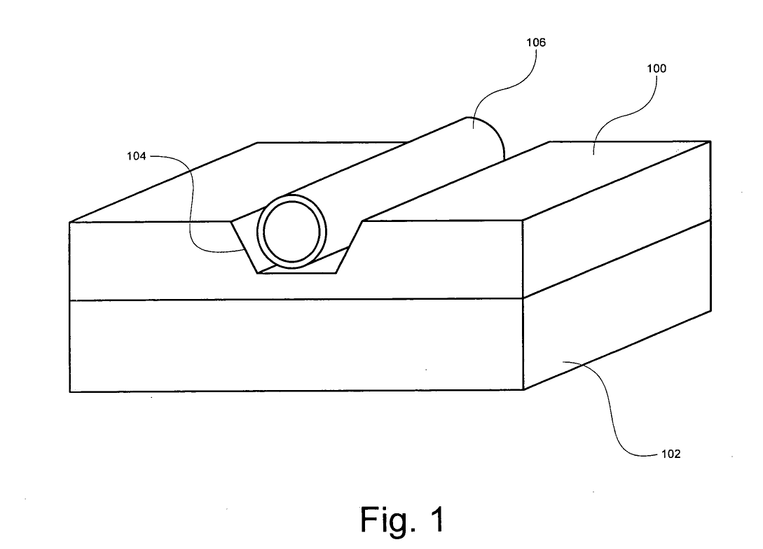

Carbon nanotubes may be used for interconnections on an integrated circuit, replacing or being used in conjunction with traditional copper metal. Carbon nanotubes conduct electrons ballistically, in other words, without the scattering that gives copper its resistance. Dielectric material with a low dielectric constant (low-k), such as amorphous, carbon based insulation or fluorine doped silicon dioxide, may be used to insulate the carbon nanotubes. For instance, carbon-doped oxide (CDO) is a low-k dielectric material that may be used as the carbon based insulation. FIG. 1 illustrates carbon based insulation and a carbon nanotube used for interconnections on an integrated circuit.

With reference to FIG. 1, a carbon based low-k dielectric material, such as a CDO layer 100, is deposited onto an integrated circuit structure 102. Formed on or within the integrated circuit structure 102 are devices such as transistors, capacitors, and interconnects (not shown). The CDO layer 100 is generally considered part of the integrated circuit structure 102. In one implementation, the deposition of the CDO layer 100 may be performed by techniques well known to those of ordinary skill in the art, such as chemical vapor deposition (CVD), physical vapor deposition (PVD), or plasma enhanced chemical vapor deposition (PECVD).

The CDO layer 100 is planarized using chemical mechanical polishing (CMP), as is well known by those of ordinary skill in the art. The planarized CDO layer 100 may be patterned using conventional photolithography and etching techniques to create a patterned layer. In one implementation, a trench 104 results from the etching process. Carbon based precursor material may then be deposited into the trench 104 within the CDO layer 100. A carbon nanotube 106 may be created from the carbon based precursor material and functions as an electrical interconnection between electrical contacts within the integrated circuit structure 102. This process may be repeated to create multiple layers of chip level interconnections using carbon nanotubes 106 and CDO layers 100.

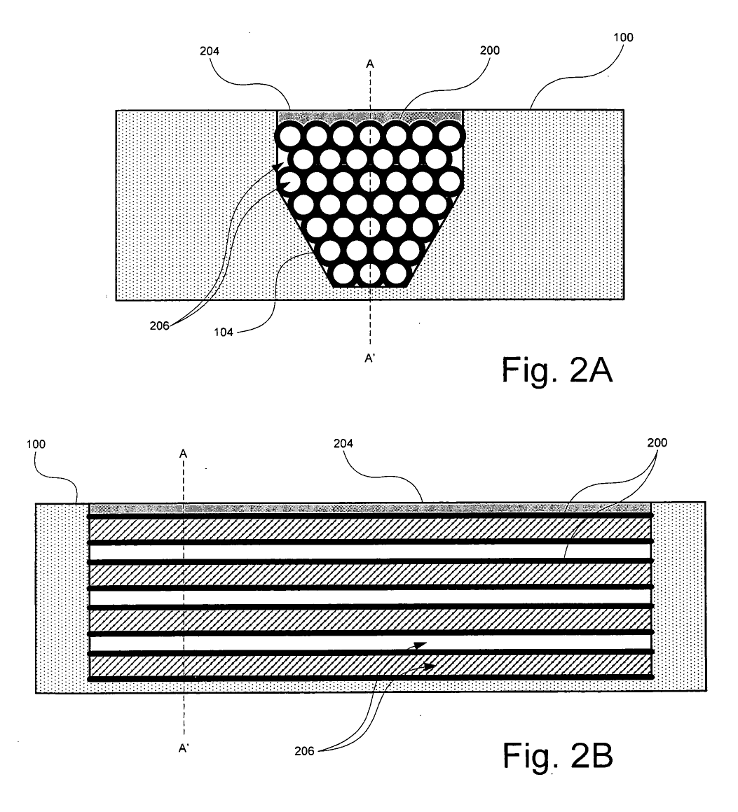

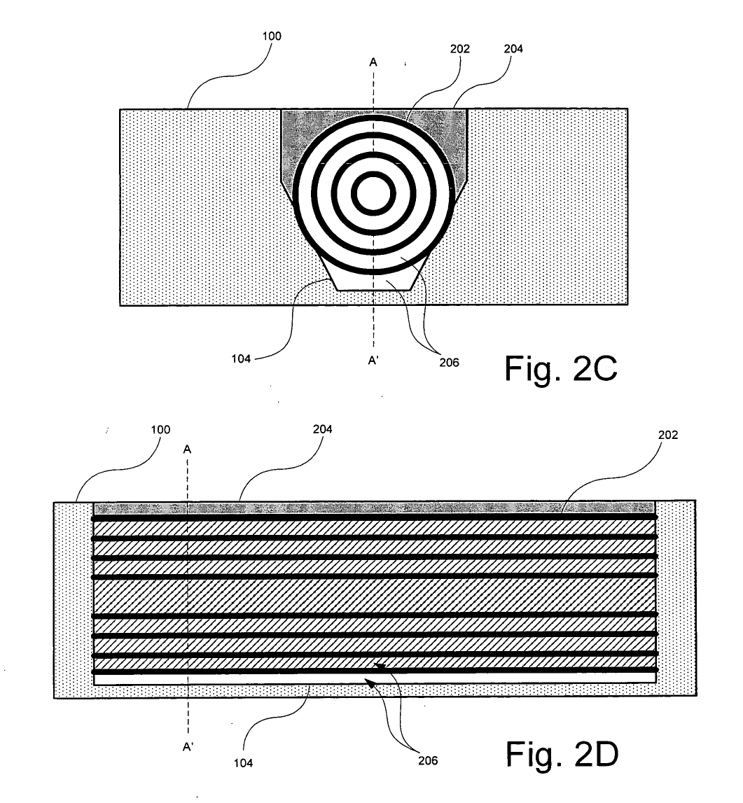

FIGS. 2A through 2D are schematic representations of conventional carbon nanotube interconnect structures. FIGS. 2A and 2B are based on a bundle of single walled nanotubes 200. FIGS. 2C and 2D are based on a multi-walled nanotube 202. Line A-A′ shows where the cross-sections are taken. Both carbon nanotube interconnect structures are shown with top-down evaporation of metal. An electrical contact 204 to the carbon nanotube bundle 200 only interfaces with the top layer of nanotubes, while an electrical contact 204 to the multi-walled carbon nanotube 202 only interfaces with the outer wall nanotube.

As shown, conventional interconnect structures formed using carbon nanotubes do not utilize the full current-carrying capacity of the graphene sheets of the carbon nanotubes. This is partly due to voids 206 that exist within a bundle of carbon nanotubes and voids 206 that exist between the shells of multi-walled carbon nanotubes, as demonstrated in FIGS. 2A through 2D. This is also partly due to the fact that electrical contact is not made to all of the graphene sheets constituting a carbon nanotube bundle 200 or a multi-walled carbon nanotube 202. Only the top layer of a bundle of single-walled carbon nanotubes 200 or a multi-walled nanotube 202 is contacted due to the nature of the conventional processes used, such as highly unidirectional metal deposition processes using thermal or electron beam evaporation. When only the top layer of a bundle of single-walled carbon nanotubes 200 or a multi-walled nanotube 202 is contacted, electron tunneling is necessary to electrically address lower lying layers or tubes. Unfortunately, electron tunneling is associated with a resistance that is dependent upon the inter-electronic coupling between nanotubes and the distance between the nanotubes.

As such, in accordance with implementations of the invention, a novel carbon nanotube interconnect structure may be formed through a conformal and substantially complete deposition of metal on all of the graphene sheets constituting the carbon nanotube interconnect structure. Novel contacts may also be formed on the ends of the carbon nanotube interconnect structure that are physically coupled to substantially all of the graphene sheets constituting the carbon nanotube interconnect structure. Interconnect structures formed in accordance with the invention may realize a greater portion of the current-carrying potential of the carbon nanotubes.

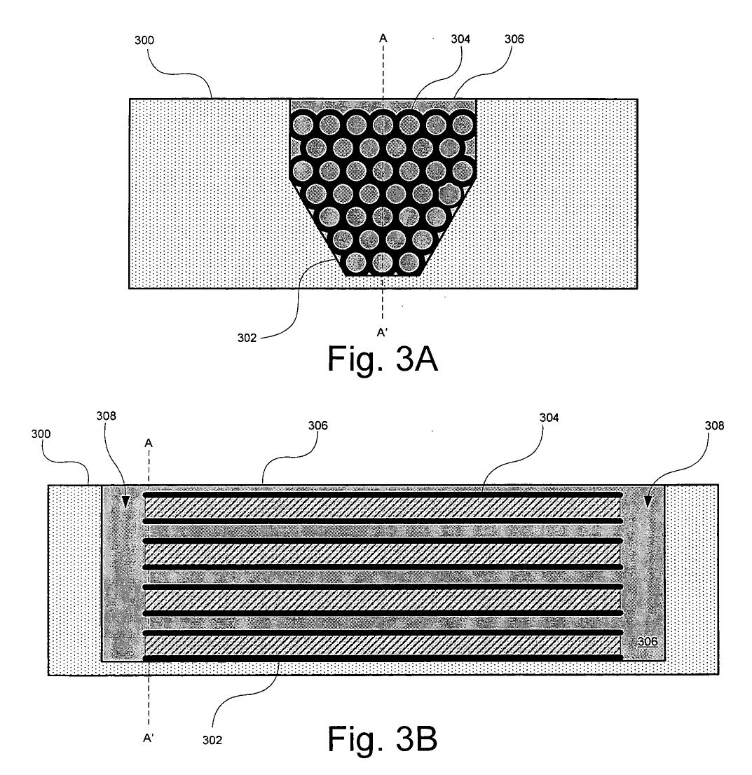

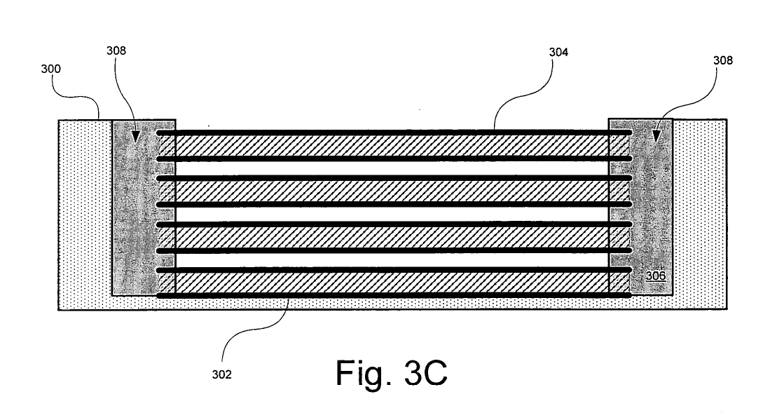

FIGS. 3A and 3B are cross-sectional front and side views of an implementation of the invention. A dielectric layer 300 is shown that includes a trench 302. The dielectric layer 300 may be part of an integrated circuit and may be formed over a semiconductor substrate, an interlayer dielectric layer, or a metallization layer, for example. The dielectric layer 300 may be formed using conventional dielectric materials, including but not limited to silicon dioxide (SiO₂) and carbon doped oxide (CDO). The trench 302 may be formed in the dielectric layer 300 using known masking and etching (i.e., photolithography) techniques. The trench 302 may be used to define an interconnect structure.

An interconnect structure may be formed within the trench 302 using one or more carbon nanotubes 304. FIGS. 3A and 3B illustrate an implementation consisting of a bundle of single-walled carbon nanotubes 304. In alternate implementations, each carbon nanotube 304 of the bundle may consist of either a single-walled or a multi-walled carbon nanotube 304. The bundle may contain only single or multi-walled carbon nanotubes 304, or the bundle may contain a mixture of single-walled and multi-walled carbon nanotubes 304. The carbon nanotubes 304 may be formed separate from the trench 302 and then deposited into the trench 302, or the carbon nanotubes 304 may be formed directly within the trench 302 using one or more precursor materials that are deposited into the trench 302 and then converted into carbon nanotubes 304.

In accordance with an implementation of the invention, a metal 306 may be conformally deposited onto each of the graphene sheets that constitute the carbon nanotubes 304. The metal 306 may be used to fill voids that exist within each carbon nanotube 304 and voids that exist between the carbon nanotubes 304. The metal 306 may be deposited as multiple thin, conformal layers using processes such as atomic layer deposition (ALD), physical vapor deposition (PVD), and electroless plating. In implementations of the invention, metals that may be used to conformally fill the carbon nanotubes 304 include, but are not limited to, copper (Cu), aluminum (Al), gold (Au), platinum (Pt), palladium (Pd), rhodium (Rh), ruthenium (Ru), osmium (Os), silver (Ag), iridium (Ir), titanium (Ti), and alloys of any or all of these metals. In some implementations, the metal or metals used may undergo chemical surface modification to provide improved electronic coupling.

Metallized contacts 308 may be formed at each end of the bundle of carbon nanotubes 304, thereby capping the ends of the interconnect structure and providing electrical contacts to the interconnect. Unlike the conventional contacts described with reference to FIGS. 2A and 2B, the metallized contacts 308 shown in FIGS. 3A and 3B are coupled to substantially all of the carbon nanotubes 304 that are used in the interconnect structure. In some implementations of the invention, the metallized contacts 308 may be formed using the metal 306 used to conformally fill the carbon nanotubes 304. In other implementations, the metal used to form the metallized contacts 308 may be different than the metal 306 used to conformally fill the carbon nanotubes 304. As such, the metallized contacts 308 may be formed using metals that include, but are not limited to, Cu, Al, Au, Pt, Pd, Rh, Ru, Os, Ag, Ir, Ti, and alloys of any or all of these metals. Again, the metal or metals used may undergo chemical surface modification to provide improved electronic coupling.

FIG. 3C illustrates another implementation of the invention where only a portion of the carbon nanotubes 304 are conformably filled with the metal 306. In this implementation, the metal 306 may be deposited to conformally fill the ends of the carbon nanotubes 304 and to form the metallized contacts 308. The voids within and between the carbon nanotubes 304 are allowed to remain unfilled and electric current is conducted primarily through the graphene sheets.

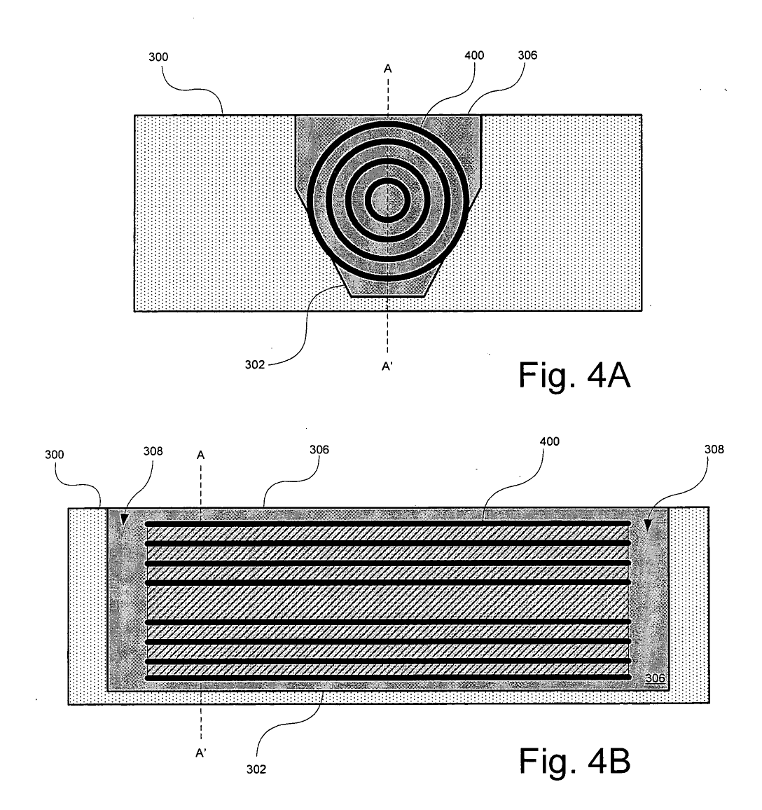

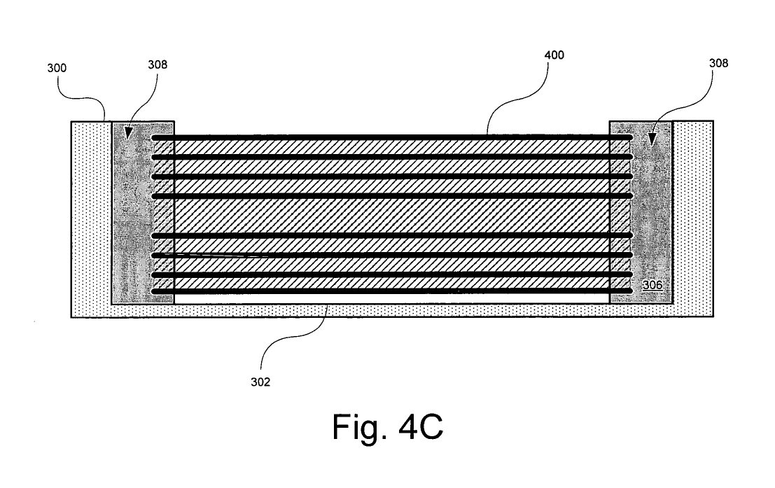

FIGS. 4A and 4B are cross-sectional front and side views of another implementation of the invention. The dielectric layer 300 is shown that includes the trench 302. As before, the dielectric layer 300 may be part of an integrated circuit and may be formed using conventional dielectric materials. The trench 302 may be formed in the dielectric layer 300 and may be used to define an interconnect structure. In this implementation, an interconnect structure may be formed within the trench 302 using at least one multi-walled carbon nanotube 400. In other implementations, more than one multi-walled carbon nanotube 400 may be used to form the interconnect structure.

Similar to what is shown in FIGS. 3A and 3B, in this implementation the metal 306 may be conformally deposited onto each of the graphene sheets that forms the multi-walled carbon nanotube 400. The metal 306 may be deposited as multiple thin, conformal layers using processes such as ALD, PVD, and electroless plating. The metal 306 fills voids that exist between each of the multiple walls of the carbon nanotube 400 as well as the void that exists at the center of the carbon nanotube 400. If more than one multi-walled carbon nanotube 400 is used, the metal 306 may also fill voids that exist between the multi-walled carbon nanotubes 400. As described above, the metal 306 used to conformally fill the multi-walled carbon nanotube 400 may include, but is not limited to, Cu, Al, Au, Pt, Pd, Rh, Ru, Os, Ag, Ir, Ti, and alloys of any or all of these metals.

Metallized contacts 308 may again be formed at each end of the multi-walled carbon nanotube 400, thereby capping the ends of the interconnect structure and providing electrical contacts to the interconnect. The metallized contacts 308 shown in FIGS. 4A and 4B are coupled to substantially all of the graphene sheets that make up the multi-walled carbon nanotube 400. In some implementations, the metallized contacts 308 may be formed from the same metal 306 used to conformally fill the carbon nanotubes 400, while in other implementations the metal used to form the metallized contacts 308 may be different than the metal 306 used to conformally fill the carbon nanotubes 400.

FIG. 4C illustrates another implementation of the invention where only a portion of the multi-walled carbon nanotube 400 is conformally filled by the metal 306. In this implementation, the metal 306 may be deposited to conformally fill the ends of the multi-walled carbon nanotube 400 and to form the metallized contacts 308. The voids within the multi-walled carbon nanotube 400 are allowed to remain unfilled and electric current is conducted primarily through the graphene sheets.

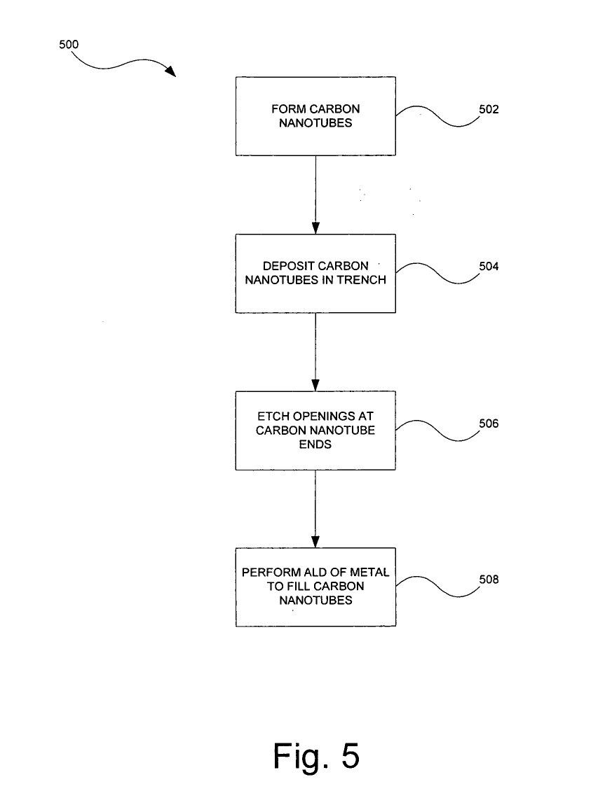

FIG. 5 is a method 500 of forming a carbon nanotube interconnect structure in accordance with an implementation of the invention. The method 500 utilizes novel chemical metal deposition methods to form the carbon nanotube interconnect structure and associated metallized contacts.

In accordance with this implementation, one or more carbon nanotubes 304, including but not limited to single-walled, double-walled or multi-walled nanotubes, may be grown using conventional methods (502 of FIG. 5). For instance, the carbon nanotubes may be grown on solid substrates, patterned substrates, or porous substrates, or they may be formed as part of a precipitate or second phase in a solution.

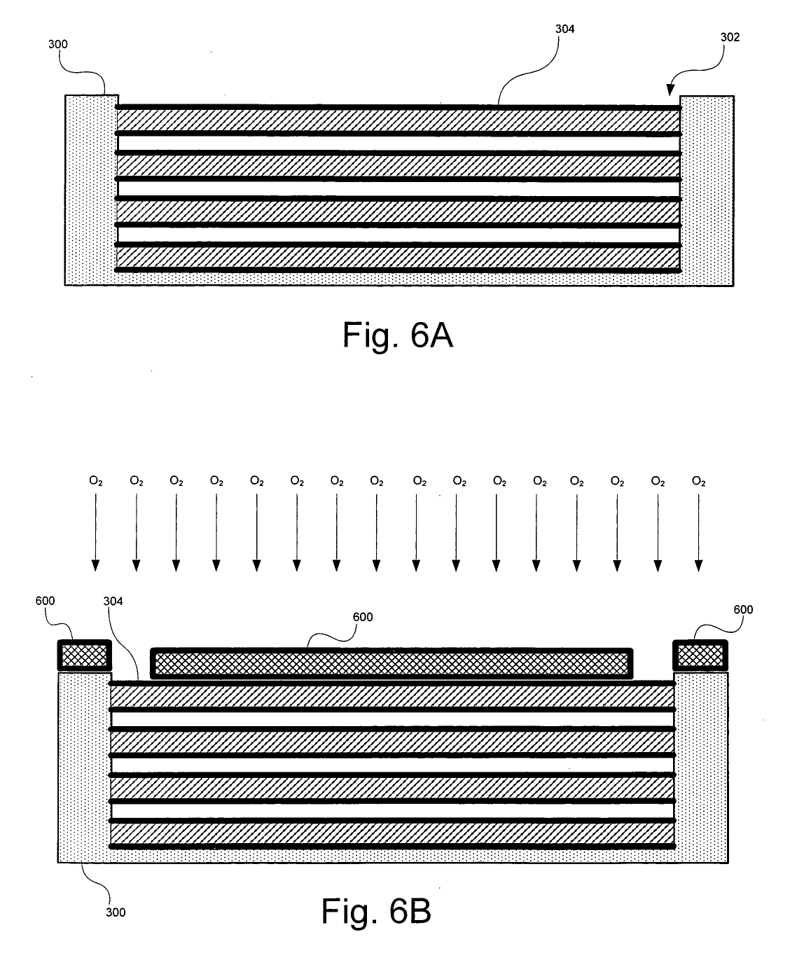

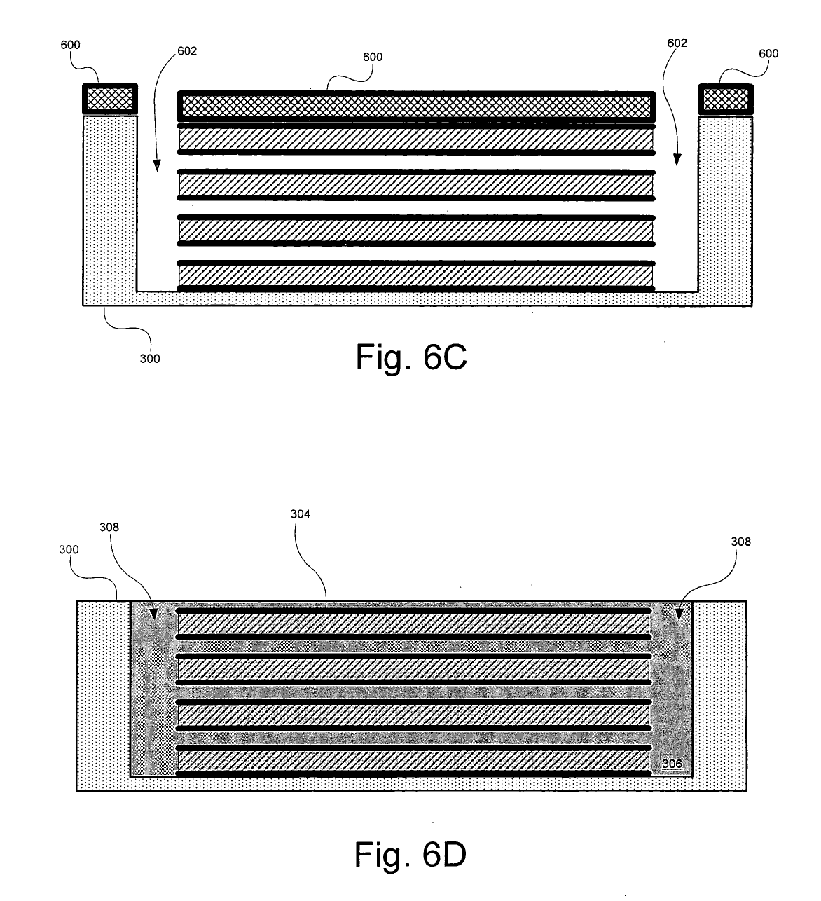

One or more of the carbon nanotubes are then placed into the trench 302 within the dielectric layer 300 to form an interconnect structure (504 of FIG. 5). Alternately, the carbon nanotubes may be grown directly within the trench. In some implementations of the invention, a bundle of carbon nanotubes 304 are placed within the trench 302 to form the interconnect structure, as shown in FIG. 6A. In other implementations, at least one single or multi-walled carbon nanotube may be placed or grown within the trench.

To form contacts at specific areas along the length of the carbon nanotube bundle, common lithographic methods may be used to create openings into the interconnect structure (506 of FIG. 5). For instance, the carbon nanotubes 304 may be covered by a photoresist layer, as is well known in the art. The photoresist layer may be patterned by lithography to form a mask 600 over the carbon nanotubes 304 that exposes the ends of the carbon nanotubes 304 where the electrical contacts are to be formed, as shown in FIG. 6B. Plasma etching, such as oxygen etching (shown in FIG. 6B as O₂), may be applied to burn out the exposed portions of the carbon nanotubes 304. The lithography may include photolithography, e-beam lithography, or other lithography known in the art. While an oxygen plasma etching process is described, other techniques are possible as well.

The plasma etching process forms openings 602 in the carbon nanotubes 304 that generally extend all the way down to the bottom surface of the trench 302, as shown in FIG. 6C. These openings 602 provide an entrance for the metal 306 to enter the exposed carbon nanotubes 304 during a subsequent deposition process. The openings 602 also provide a site for the metallized contacts 308 to be formed. Each opening 602 exposes substantially all of the carbon nanotubes 304 in the interconnect structure, thereby allowing the later formed metallized contacts 308 to become coupled to substantially all of the carbon nanotubes 304 of the interconnect.

After the openings 602 have been etched, the mask 600 is removed and the method 500 utilizes atomic layer deposition (ALD) of metal 306 to conformally fill the carbon nanotubes 304 and to form the metallized contacts 308 (508 of FIG. 5). ALD enables the conformal deposition of metal on all of the graphene sheets that are included in either a bundle of carbon nanotubes or in one or more multi-walled carbon nanotubes. ALD is a surface-limited chemical vapor deposition reaction. As such, ALD processes form thin, conformal films of metal that are limited to the surface area of the graphene sheets. Multiple layers of these thin films may be produced during repeated ALD cycles to substantially or completely fill the voids within the carbon nanotubes 304, as shown in FIG. 6D.

Known ALD precursor chemistries may be utilized that are appropriate for the metal chosen to conformally fill the carbon nanotubes. For example, in one implementation of the invention, platinum metal may be chosen to conformally fill the carbon nanotubes and to form the metallized contacts. In this implementation, known precursors chemistries for platinum metals, including but not limited to beta-diketonates, cyclopentadienyl, arenes, allyls, and carbonyls, may be used with an appropriate co-reactant such as oxygen or hydrogen. Again, complete surface conformality and coverage is expected with ALD as it is a surface limited deposition method.

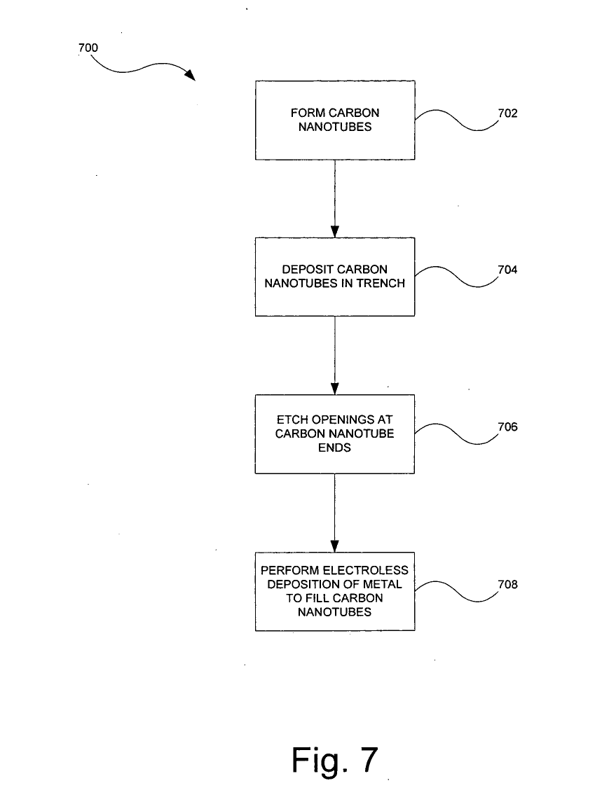

FIG. 7 is a method 700 of forming a carbon nanotube interconnect structure in accordance with another implementation of the invention. In this implementation, one or more carbon nanotubes, including but not limited to single-walled, double-walled or multi-walled nanotubes, may be grown using conventional methods (702). For instance, the carbon nanotubes may be grown on solid substrates, patterned substrates, or porous substrates, or they may be formed as part of a precipitate or second phase in a solution.

One or more of the carbon nanotubes are used to form an interconnect structure by being placed into a trench within a dielectric layer (704). If the carbon nanotubes are grown directly within the trench, then this portion of the process may be eliminated. In implementations of the invention, a bundle of carbon nanotubes are placed within the trench to form the interconnect structure. Alternately, at least one single or multi-walled carbon nanotube may be placed or grown within the trench.

Common lithographic methods may be used to create openings into the interconnect structure (706). The etching processes may remove a portion of the carbon nanotubes to form openings through which a metal may be deposited and to allow metallized contacts to be formed that are coupled to substantially all of the graphene sheets that constitute the carbon nanotubes used in the interconnect structure.

After openings into the carbon nanotubes have been etched, rather than relying on ALD, the method 700 utilizes an electroless metal deposition in supercritical carbon dioxide (scCO₂) to conformally fill the carbon nanotubes with metal and to form the metallized contacts (708). Electroless metal deposition in scCO₂ enables the conformal deposition of metal on all of the graphene sheets that constitute a carbon nanotube bundle. This process may substantially or completely fill the core diameter of single or multi-walled carbon nanotubes with a metal, for example platinum or palladium.

As is known in the art, electroless metal deposition involves the deposition of a metal from a solution onto a substrate by a controlled chemical reduction reaction. The metal or metal alloy being deposited generally catalyzes the controlled chemical reduction reaction. Electroless metal deposition has several advantages over electroplating, another common plating process well known in the art. For example, electroless plating requires no electrical charge applied to the substrate, electroless plating generally results in a more uniform and nonporous metal layer on the target, and electroless metal deposition is autocatalytic and continuous once the plating process is initiated.

In accordance with the invention, a supercritical liquid such as scCO₂ is used as the medium for the electroless plating solution. Supercritical liquids are known to penetrate the very small voids, gaps, and inner walls of carbon nanotubes due to their negligible viscosity. Supercritical liquids also leave little or no residues behind since the supercritical liquid, for example scCO₂, will evaporate as a gas (i.e., CO₂) once the conditions that make it supercritical are removed. Furthermore, as will be described below, supercritical liquids such as scCO₂ tend to enhance the interaction between the carbon nanotube surface and the metal ions in the electroless plating solution.

In an implementation of the invention, the electroless plating solution includes a supercritical liquid (e.g., scCO₂), a compound containing the metal to be deposited (e.g., a metal salt), and a reductant. In one implementation, the metal salt may include, but is not limited to, palladium hexafluoroacetylacetonate (Pd(hfac)₂), which is soluble in scCO₂, and the reductant may include, but is not limited to, hydrogen (H₂). Electroless metal deposition in scCO₂ works similar to electroless deposition of metal in water—the metal salt and the reductant are dissolved into the scCO₂ and the electroless plating process is carried out.

In another implementation, a conventional, non-supercritical, electroless plating chemistry may be used. In one such implementation, palladium may be used in the electroless plating process. In some implementations, the palladium deposition may be followed by a copper deposition. A standard electroless plating solution is similar to the solutions described above but uses a liquid such as water in lieu of a supercritical liquid.

In implementations of the invention, the electroless plating solutions described above may further include complexing agents (e.g., an organic acid or amine) that prevent chemical reduction of the metal ions in solution while permitting selective chemical reduction on a surface of the target, chemical reducing agents (e.g., hypophosphite, dimethylaminoborane (DMAB), formaldehyde, hydrazine, or borohydride) for the metal ions, buffers (e.g., boric acid, an organic acid, or an amine) for controlling the pH level of the solution, and various optional additives such as solution stabilizers (e.g., pyridine, thiourea, or molybdates) and surfactants (e.g., a glycol). It is to be understood in all of the above described electroless plating processes that the specific composition of the plating solution will vary depending on the desired plating outcome.

In further implementations of the invention, the wetting behavior of the carbon nanotubes may be modified to enhance the electroless plating process. The wetting of the carbon nanotubes generally enables an improved interaction between the carbon nanotube surface and the metal ions in the plating solution. Furthermore, because the use of scCO₂ as the plating solution medium also enhances the interaction of the surface of the carbon nanotubes with the metal ions, combining the use of scCO₂ with a process for wetting the carbon nanotubes results in an improved and more complete metal deposition.

It is believed that the improved interaction between the carbon nanotube surface and the metal may be attributed to the surfactant-like qualities of the scCO₂ and of the hydrophilic groups present when the wetting behavior of the carbon nanotubes has been modified. The scCO₂ and the hydrophilic groups may also enhance the solvent, slurry, or medium effects thus leading to an enhanced interaction. It is further believed that the improved interaction between the carbon nanotube surface and the metal may lead to an improved adhesion between the carbon nanotube surface and the metal due to a temporary or permanent decrease in surface energy. This decrease in surface energy leads to the exposure of a greater portion of the carbon nanotube surface to the electroless plating solution and prevents the carbon nanotubes from balling up and minimizing their surface energy in contact with the metal.

The improved interaction between the carbon nanotube surface and the metal may also be attributed to increased capillary action that results from modifying the wetting behavior of the carbon nanotubes. The electroless plating solution, and the metal ions in particular, tend to be drawn into the carbon nanotubes by capillary action. Therefore, increasing the hydrophilicity of the carbon nanotubes increases the penetration of electroless plating solution and metal ions within the nanotubes.

In implementations of the invention, the wetting behavior of the surface of the carbon nanotubes may be attenuated through chemical modification. For example, the introduction of hydrogen-bonding functionalities may increase the hydrophilicity of the carbon nanotubes, thereby leading to enhanced water miscibility. Functionalities that favor these hydrophilic interactions include, but are not limited to, amines, amides, hydroxyls, carboxylic acids, aldehydes, and fluorides.

There are many known processes by which carbon nanotubes may be functionalized. Some of these processes include, but are not limited to, the following: (1) carboxylic acid functionalization through nitric acid oxidation; (2) carboxyl reduction to alcohols or aldehydes (e.g. NaBH₄); (3) alcohol oxidation to aldehydes or carboxylic acids (e.g. pyridinium chlorochromate, Swern oxidation, etc); (4) amination of alcohols or carboxylic acids (e.g. NaN₃, SOCl₂/NH₃, etc); (5) alkylation through the generation of alkyl radicals with alkyliodides/benzoyl peroxide; (6) 1,3-dipolar cycloadditions to the aromatic carbon nanotube framework; (7) arylation of carbon nanotubes with 4-chlorobenzenediazonium tetrafluoroborate, thus yielding a pendant aryl chloride functionality; (8) water solubilization of carbon nanotubes through reactive coating with polymers such as polyarleneethynlene; (9) attachment of metallic groups to sidewalls through [2+1]-cycloaddition attachment of gold colloids; (10) attachment of bio-molecules to carbon nanotubes (e.g., amino acids, proteins, DNA, etc.).

The aryl chlorides are prone to further functionalization including inter-carbon nanotube Heck-coupling reactions to yield covalently linked nanotubes and conversion of aryl iodides into amines, alcohols, or fluorides. This functionalization would be expected to increase carbon nanotube hydrophilicity leading to water miscibility. The methods presented herein may be employed for basement film-generation or wetting of the carbon nanotubes. It is believed that these methods for wetting carbon nanotubes may be applied for any transition metal, including but not limited to palladium, platinum, rhodium, ruthenium, gold, osmium, silver, and iridium.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing at least one carbon nanotube within a trench;
etching at least one portion of the carbon nanotube to create an opening;
conformally depositing a metal layer on the carbon nanotube through the opening; and
forming a metallized contact at the opening that is substantially coupled to the carbon nanotube.

2. The method of claim 1, wherein the trench is formed in a dielectric material.

3. The method of claim 1, wherein the carbon nanotube comprises a bundle of carbon nanotubes.

4. The method of claim 1, wherein the carbon nanotube comprises a multi-walled carbon nanotube.

5. The method of claim 1, wherein the conformally depositing of the metal layer comprises conformally depositing multiple metal layers to substantially fill voids within the carbon nanotube.

6. The method of claim 3, wherein the conformally depositing of the metal layer comprises conformally depositing multiple metal layers to substantially fill voids within the carbon nanotube and voids between carbon nanotubes of the bundle.

7. The method of claim 4, wherein the conformally depositing of the metal layer comprises conformally depositing multiple metal layers to substantially fill voids between the multiple walls of the carbon nanotube and a void at the center of the carbon nanotube.

8. The method of claim 1, wherein the conformally depositing of the metal layer is performed using an atomic layer deposition process.

9. The method of claim 1, wherein the conformally depositing of the metal layer is performed using an electroless plating process

10. The method of claim 9, wherein the electroless plating process utilizes a plating solution formed from a supercritical liquid of carbon dioxide.

11. The method of claim 3, wherein the metallized contact is substantially coupled to all of the carbon nanotubes of the bundle.

12. The method of claim 4, wherein the metallized contact is substantially coupled to all of the walls of the multi-walled carbon nanotube.

13. The method of claim 1, wherein the deposited metal layer comprises Cu, Al, Au, Pt, Pd, Rh, Ru, Os, Ag, Ir, Ti, or an alloy of one or more of these metals.

14. The method of claim 1, wherein the metallized contact comprises Cu, Al, Au, Pt, Pd, Rh, Ru, Os, Ag, Ir, Ti, or an alloy of one or more of these metals.

15. A method comprising:
providing a bundle of carbon nanotubes within a trench;
etching a first end of the bundle of carbon nanotubes to create a first opening;
etching a second end of the bundle of carbon nanotubes to create a second opening;
conformally depositing multiple metal layers on each of the carbon nanotubes of the bundle through the openings; and
forming metallized contacts in the first and second openings that are substantially coupled to all of the carbon nanotubes of the bundle.

16. The method of claim 15, wherein the trench is formed in a dielectric material comprising silicon dioxide or carbon doped oxide.

17. The method of claim 15, wherein the process of conformally depositing multiple metal layers substantially fills voids within the carbon nanotubes and voids between carbon nanotubes of the bundle.

18. The method of claim 15, wherein the process of conformally depositing multiple metal layers is performed using an atomic layer deposition process.

19. The method of claim 15, wherein the process of conformally depositing multiple metal layers is performed using an electroless plating process in a supercritical liquid of carbon dioxide.

20. The method of claim 15, wherein the deposited metal layers comprise Cu, Al, Au, Pt, Pd, Rh, Ru, Os, Ag, Ir, Ti, or an alloy of one or more of these metals.

21. The method of claim 15, wherein the metallized contacts comprise Cu, Al, Au, Pt, Pd, Rh, Ru, Os, Ag, Ir, Ti, or an alloy of one or more of these metals.

22. A method comprising:
providing at least one carbon nanotube within a trench;
etching at least one portion of the carbon nanotube to create an opening;
modifying the wetting behavior of a surface of the carbon nanotube to increase its hydrophilicity; and
performing an electroless plating process on the carbon nanotube using an electroless plating bath that comprises a supercritical liquid.

23. The method of claim 22, wherein the etching comprises:
depositing a photoresist layer;
patterning the photoresist layer;
developing the photoresist layer;
etching the carbon nanotube; and
removing the developed photoresist layer.

24. The method of claim 23, wherein the etching comprises a plasma etching process.

25. The method of claim 22, wherein the modifying of the wetting behavior comprises introducing hydrogen-bonding functionalities into the carbon nanotubes.

26. The method of claim 25, wherein the hydrogen-bonding functionalities comprises at least one of amines, amides, hydroxyls, carboxylic acids, aldehydes, and fluorides.

27. The method of claim 22, wherein the supercritical liquid comprises supercritical carbon dioxide.

28. The method of claim 22, wherein the electroless plating bath further comprises palladium hexafluoroacetylacetonate and hydrogen.

29. The method of claim 22, wherein the trench is located within a dielectric layer on a semiconductor substrate.

30. The method of claim 29, wherein the carbon nanotube is formed within the trench.

31. An apparatus comprising:
a bundle of carbon nanotubes mounted within a trench;
a metallized contact mounted at an end of the bundle of carbon nanotubes, wherein the metallized contact is directly coupled to substantially all of the carbon nanotubes of the bundle; and
at least one metal layer conformally deposited on a surface of each carbon nanotube, wherein each metal layer covers substantially the entire surface of each carbon nanotube.

32. The apparatus of claim 31, further comprising a second metallized contact mounted at a second end of the bundle of carbon nanotubes, wherein the second metallized contact is directly coupled to substantially all of the carbon nanotubes of the bundle.

33. The apparatus of claim 31, further comprising multiple metal layers conformally deposited on the surface of each carbon nanotube, wherein the multiple layers substantially fill the voids within the bundle of carbon nanotubes.
